(19) United States
(12) Patent Application Publication
(10) Pub. No.: US 2026/0343869 A1
(43) Pub. Date: Oct. 29, 2026

(54) MEMORY, MEMORY SYSTEMS, AND ELECTRONIC DEVICES

(71) Applicant: Yangtze Memory Technologies Co., Ltd., Wuhan (CN)

(72) Inventor: Zhaohong Li, Wuhan (CN)

(21) Appl. No.: 19/306,569

(22) Filed: Aug. 21, 2025

(30) Foreign Application Priority Data
Apr. 29, 2025 (CN) 202510559010.7

(51) Int. Cl. H10B 12/00; G11C 11/4074; H10B 80/00; H10W 90/00

(52) U.S. Cl. CPC H10B 12/50; G11C 11/4074; H10B 80/00; H10W 90/00; H10W 90/792

(57) ABSTRACT

A memory includes: a first semiconductor structure that includes a metal layer and a capacitor group in a charge pump, the capacitor group includes a plurality of capacitors connected to the metal layer, and the metal layer is configured to connect the plurality of capacitors in parallel; and a second semiconductor structure bonded to the first semiconductor structure, the second semiconductor structure includes a voltage regulation circuit in the charge pump.

### CROSS-REFERENCE TO RELATED APPLICATION

This application claims priority to and the benefit of Chinese Patent Application 202510559010.7, filed on Apr. 29, 2025, which is hereby incorporated by reference in its entirety.

### TECHNICAL FIELD

Examples of the present disclosure relates to the field of memory technology, and particularly to memory, memory systems, and electronic devices.

### BACKGROUND

A charge pump is a circuit that utilizes the energy storage characteristics of capacitors to generate output voltages, and has a wide range of applications in memories.

The performance of charge pump is directly affected by charge storage capacity of a capacitor in the charge pump, which may be characterized by capacitance.

### BRIEF DESCRIPTION OF THE DRAWINGS

FIG. 1 is a structural block diagram of an electronic device provided in one example of the present disclosure.

FIG. 2 is a structural block diagram of an electronic device provided in another example of the present disclosure.

FIG. 3 is a schematic diagram of a solid-state drive provided in one example of the present disclosure.

FIG. 4 is a schematic diagram of a memory provided by one example of the present disclosure.

FIG. 5 is a schematic diagram of a composition structure of a memory provided in one example of the present disclosure.

FIG. 6 is a schematic diagram of a connection relationship between word lines, bit lines, and memory cells of a memory provided in one example of the present disclosure.

FIG. 7 is a schematic diagram of a memory provided by one example of the present disclosure.

FIG. 8 is a schematic diagram of a three-dimensional structure of a memory provided in one example of the present disclosure.

FIG. 9 is a schematic diagram of a connection relationship between a capacitor group and a first metal layer and a second metal layer provided in one example of the present disclosure.

FIG. 10 shows a schematic diagram of a corresponding relationship between a structure of a charge pump and a first semiconductor structure and a second semiconductor structure, and a capacitor group in a first capacitor circuit provided in one example of the present disclosure.

FIG. 11 shows a schematic diagram of a corresponding relationship between a structure of a charge pump and a first semiconductor structure and a second semiconductor structure, and two capacitor groups in a first capacitor circuit provided in one example of the present disclosure.

FIG. 12 is a schematic diagram of arrangement of regions of a memory provided in one example of the present disclosure.

FIG. 13 is a schematic diagram of arrangement of regions of a memory provided in another example of the present disclosure.

### DETAILED DESCRIPTION

In order to clarify the purpose, technical solution, and advantages of the present disclosure, a further detailed description of examples of the present disclosure will be provided below in conjunction with accompanying drawings.

It should be noted that the terms “first”, “second”, etc. used in the present disclosure are intended to distinguish similar objects and do not necessarily describe a specific order or sequence. It should be understood that data used in this way may be interchanged under appropriate circumstances, so that the examples of the present disclosure may be implemented in various orders. The implementations described in the following examples do not represent all implementations consistent with the present disclosure. On the contrary, they are only examples consistent with some aspects of the present disclosure.

In memories, further research is needed on how to design a capacitor in a charge pump properly.

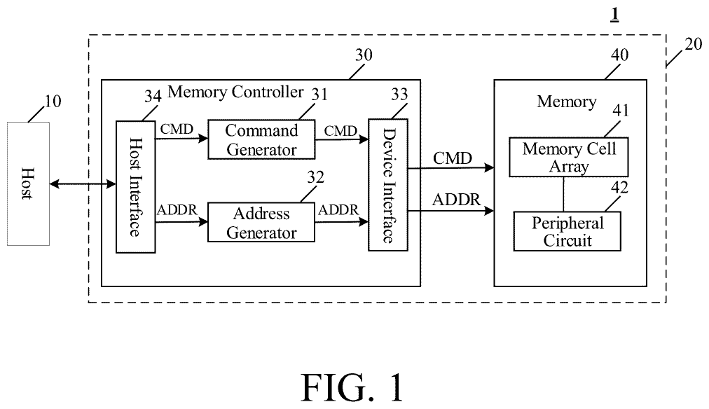

FIG. 1 shows a structural block diagram of an electronic device provided in one example of the present disclosure. The electronic device 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device with storage therein. As shown in FIG. 1, the electronic device 1 may include a host 10 and a memory system 20. The memory system 20 includes a memory controller 30 and one or more memories 40. The host 10 may be a processor of an electronic device, such as a Central Processing Unit (CPU) or a Graphic Processing Unit (GPU). The host 10 may be configured to send data to or receive data from the memory 40. The controller 30 is coupled to the memory 40 and the host 10, and configured to control the memory 40. The controller 30 may manage data stored in the memory 40 and communicate with the host 10.

The controller 30 may be configured to control operations of the memory 40, such as read, erase, write, and refresh operations. In some implementations, the controller 30 is further configured to process error correction codes (ECC) for data read from or written to the memory 40. The controller 30 may also perform any other suitable function, such as formatting the memory 40.

In some examples, the controller 30 and one or more memories 40 may be integrated into various types of electronic devices. For example, the controller 30 may be integrated into the north bridge of the computer motherboard or directly integrated into the computer CPU, and multiple memories 40 may be integrated into a memory module. That is to say, the memory system 20 may be implemented and packaged into different types of end electronic products.

The controller 30 may send/receive data to/from the host 10, and may send commands (CMD) and addresses (ADDR) to the memory. The controller 30 may include a command generator 31, an address generator 32, a device interface 33, and a host interface 34. The host interface 34 may receive commands and addresses from the host 10, and the command generator 31 may generate commands to be provided to the memory 40 by decoding the commands received from the host 10, and may provide corresponding commands to the memory 40 through the device interface 33.

The address generator 32 in the controller 30 may generate row and column addresses to be accessed in the memory cell array 41 by decoding the addresses received from the host interface 34. In addition, the address generator 32 may generate the addresses of memory banks to be accessed when the memory cell array 41 includes multiple memory banks.

In addition, the controller 30 may control operations of the memory, such as writing and reading, by providing various signals to the memory 40 via the device interface 33. For example, the controller 30 may provide a write command to the memory 40. The write command is used to instruct the memory 40 to perform a write operation to store data in the memory 40.

In some examples, the memory 40 includes a memory cell array 41 and a peripheral circuit 42, wherein the memory cell array 41 includes multiple memory banks, each bank includes multiple memory blocks, each memory block includes multiple memory cell rows and multiple memory cell columns, each memory cell row is coupled to one corresponding word line, and each memory cell column is coupled to one corresponding bit line. The peripheral circuit 42 may write data to or read data from the memory cell array 41 based on commands and addresses received from the controller 30, or provide control signals to the row decoding circuit and column decoding circuit for refreshing the memory cells included in the memory cell array 41. In other words, the peripheral circuit 42 may perform all operations used to process data in the memory cell array 41. The peripheral circuit 42 may include: a control circuit corresponding to each memory block, such as Sensing Amplifier (SA) circuit and Word Line Driver (WLD) circuit; a control circuit corresponding to each memory bank, such as row decoding circuit, column decoding circuit, etc.; and a control circuit corresponding to all memory banks, such as command buffer, command decoder, address buffer, data input/output buffer, mode register, etc.

The memory 40 in any example of the present disclosure may be a volatile memory, such as Random Access Memory (RAM). For example, the memory 40 may include a Dynamic Random Access Memory (DRAM), a Synchronous DRAM (SDRAM), a Static RAM (SRAM), a Double Data Rate SDRAM (DDR SDRAM), a DDR2 SDRAM, a DDR3 SDRAM, a Phase Change RAM (PRAM), a Magnetic RAM (MRAM), a Resistive RAM (RRAM), etc. In the following examples, an example in which the memory 40 is a DRAM is described.

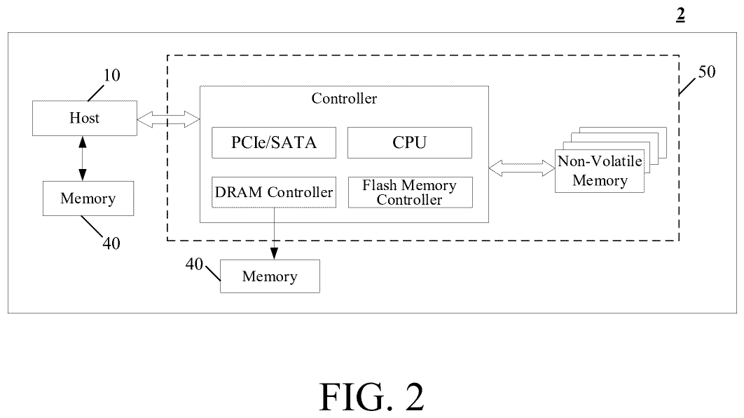

FIG. 2 shows a structural block diagram of an electronic device provided by another example of the present disclosure. In some examples, the memory 40 (DRAM) in the electronic device 2 may belong to a structure outside the memory system 50, which may be directly connected to the host 10 to serve as the main memory for the host 10 during operation, or the memory 40 may be embedded in the host 10. In some examples, the memory 40 may belong to a structure outside the memory system 50, which may be connected to the memory system 50 for use as a buffer memory, e.g., for storing mapping tables. In some examples, the memory 40 as a buffer memory may also be embedded in the controller of the memory system 50. In some other examples, the memory 40 may belong to a portion of the controller of the memory system 50, for example, the memory 40 as a buffer memory is embedded into the controller. In some examples, the controller of the memory system 50 includes a controller of the memory 40 (such as a DRAM controller) and a controller of a non-volatile memory (such as flash memory) in the memory system. In some other examples, the stacking of multiple memories 40 may be applied to High Bandwidth Memory (HBM) architectures for use as storage media.

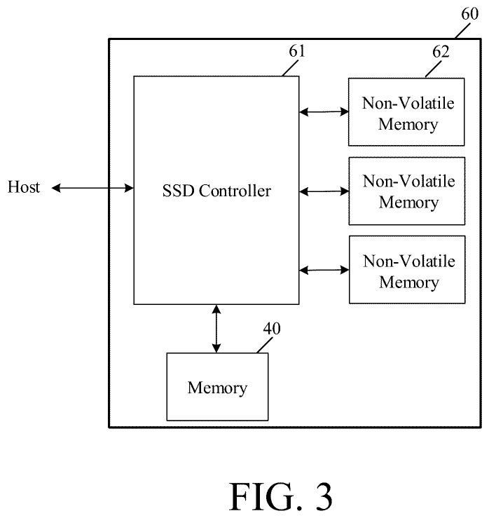

FIG. 3 shows a schematic diagram of a solid-state drive provided by one example of the present disclosure. The solid state drive (SSD) 60 may be understood as one application example of the memory system 20 or memory system 50 mentioned above. In this example, the memory 40 may be used as a buffer memory.

As shown in FIG. 3, the solid state drive (SSD) 60 may include an SSD controller 61, a memory 40, and a non-volatile memory 62. The SSD controller 61 may provide a physical connection between a host and SSD 60. That is, the SSD controller 61 may provide an interface between the host and SSD 60 in accordance with the bus format of the host. The SSD controller 61 may decode instructions provided by the host. The SSD controller 61 may access the non-volatile memory 62 based on the decoding results. The memory 40 may temporarily store written data provided by the host or data read from the non-volatile memory 62. When the host sends a read request, if data stored in the non-volatile memory 62 is cached, the memory 40 may support a cache function for providing the cached data directly to the host. The data transfer rate through the bus format of the host, such as Serial Advanced Technology Attachment (SATA) or Serial Attached Small (SAS) Computer System Interface, is much higher than the data transfer rate of a memory channel of SSD 60. That is, when the host has a significantly high interface speed, the performance degradation caused by the speed difference may be minimized by providing the memory 40 with high capacity. In addition, the memory 40 may store the address mapping table of the non-volatile memory 62. The non-volatile memory 62 may be set as a storage medium for the SSD 60. The non-volatile memory 62 may include, but is not limited to, a Not AND (NAND) Flash.

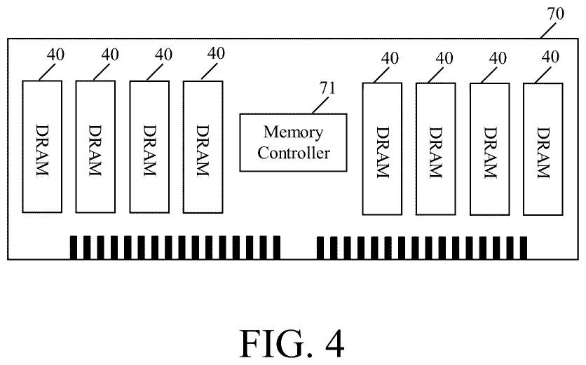

FIG. 4 shows a schematic diagram of a memory provided in one example of the present disclosure. The memory module 70 may be understood as an application example of the memory system 20 or memory system 50 mentioned above. In this example, the memory 40 may be used as a storage medium.

As shown in FIG. 4, the memory module 70 may be readily attached or installed to or removed from an electronic device through an illustrated interface. The memory module 70 may include multiple memories 40 (e.g., DRAM) and a memory controller 71. The memory module 70 may be used to write data, store data, acquire (or read) data, and/or erase data under the control of a processor of a computer. In some examples, the memory controller 71 may communicate with the memory 40 using at least one communication protocol or technical standard typically associated with, for example, Dual Inline Memory Modules (DIMMs), Registered DIMMs (RDIMMs), Load-Reduced DIMMs (LRDIMMs), Un-buffered DIMMs (UDIMMs), etc.

It should be noted that the application scenarios of the memory 40 shown in FIGS. 3 and 4 are only examples, and the present disclosure does not limit other application scenarios.

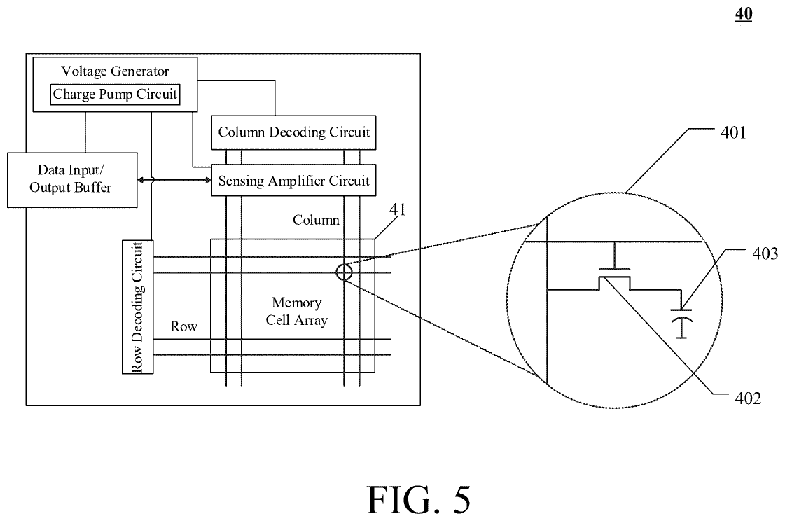

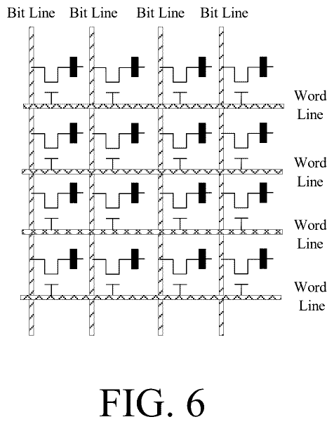

FIG. 5 shows a schematic diagram of a composition structure of a memory provided in one example of the present disclosure. FIG. 6 shows a schematic diagram of a connection relationship between word lines, bit lines, and memory cells in a memory provided in one example of the present disclosure.

The right side of FIG. 5 shows the structure of the memory cell 401 in the memory 40. The memory 40 includes at least one memory die, each memory die includes a memory cell array 41, and the memory cell array 41 includes a plurality of memory cells 401 arranged in an array. Each memory cell 401 includes a transistor 402 and a capacitor structure 403. The main operation principle of the memory cell 401 is to use the amount of charges stored in the capacitor structure 403 to represent whether a binary bit is 1 or 0. The memory cell 401 is arranged in an array and may be regarded as a typical mesh structure, which may be referred to in FIG. 6 for details. The memory cell array 41 uses rows and columns to specify addresses. By specifying intersection points of rows and columns (by specifying row and column addresses of DRAM), a controller may independently access each memory cell 401 in a memory die and perform read, write, or refresh operations on the stored data.

The left side of FIG. 5 shows the memory cell array 41 and some peripheral circuits in the memory 40, wherein a row decoding circuit selects a word line to select a row of memory cells to be accessed in response to an address input to the row decoding circuit. The row decoding circuit decodes the input address and enables (activates) the word line corresponding to the decoded address. A column decoding circuit enables the selection of a bit line. As shown in FIG. 5, the peripheral circuit also includes a voltage generator, which may generate and regulate various voltages required inside the memory 40. For example, a high voltage (such as VPP) may be provided for the row decoding circuit to drive the selected word line, a reference voltage may be provided for a sense amplifier to detect and amplify small signals on the bit line, a switch control voltage (such as VDD or negative voltage) may be provided for the column decoding circuit to connect the selected bit line to a data bus, and an interface voltage (such as VDDQ or high voltage VDDQ+, an voltage matched with an external system) may be provided for a data input/output buffer to ensure voltage level compatibility between the memory 40 and an external controller.

In order to perform write and refresh operations on the memory cell 401 of the memory 40, a voltage higher than the normal operating voltage needs to be provided. The charge pump in the voltage generator may convert a low voltage (such as VDD) into a required high voltage (such as VPP, VDDQ+), thereby providing sufficient charges for the memory cells of memory 40. The charge pump has many advantages such as low power consumption, high integration, and high stability, etc., and thus has various applications.

A charge pump is a circuit that utilizes the energy storage characteristics of capacitors to generate output voltages. Therefore, the performance of the charge pump is directly affected by the charge storage capacity of capacitors in the charge pump (which may be characterized by capacitance). In memories, further research is needed to design the capacitors in the charge pump properly.

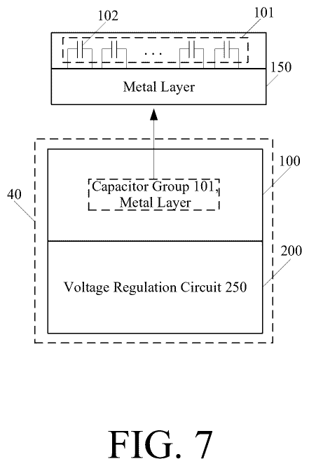

Referring to FIG. 7, FIG. 7 illustrates a schematic diagram of a memory provided in one example of the present disclosure.

The memory 40 includes a first semiconductor structure 100 and a second semiconductor structure 200 that are bonded to each other.

It should be noted that the term “bonding” referred to in examples of the present disclosure may be any suitable bonding technique, such as hybrid bonding, anodic bonding, fusion bonding, transfer bonding, adhesive bonding and eutectic bonding, etc.

The first semiconductor structure 100 includes a metal layer 150 and a capacitor group 101 in a charge pump. The capacitor group 101 includes a plurality of capacitors 102.

The plurality of capacitors 102 are connected to the metal layer 150, which is configured to connect the plurality of capacitors 102 in parallel.

The second semiconductor structure 200 includes a voltage regulation circuit 250 in the charge pump.

In some examples, the voltage regulation circuit 250 of the charge pump is connected to the input and output ends of the charge pump, thereby regulating input voltages.

The voltage regulation circuit 250 may include any other device (such as a transistor) in the charge pump besides the capacitor group 101, which is not limited by the present disclosure.

In some examples, the capacitor group 101 is connected to the voltage regulation circuit 250.

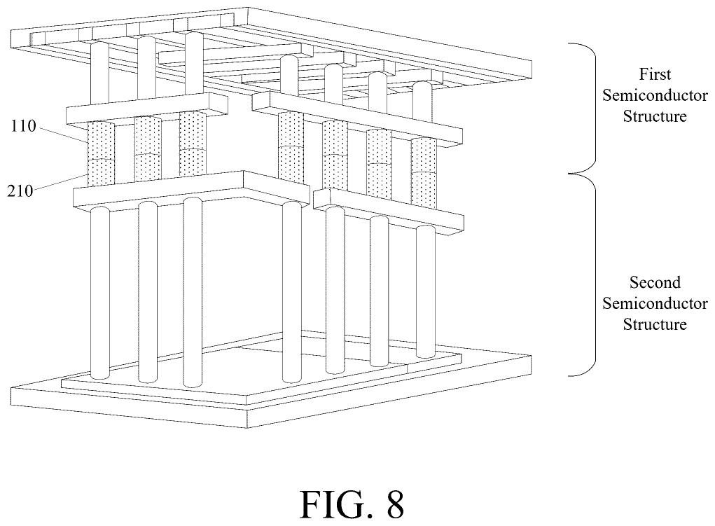

In some examples, referring to FIG. 8, the first semiconductor structure 100 includes a first bonding structure 110, and the second semiconductor structure 200 includes a second bonding structure 210. The first semiconductor structure 100 and the second semiconductor structure 200 are bonded to each other through the first bonding structure 110 and the second bonding structure 210. Materials of the first bonding structure 110 and the second bonding structure 210 include conductive materials, such as at least one of doped semiconductor materials (e.g., doped silicon, doped germanium, etc.), conductive metal nitrides (e.g., titanium nitride, tantalum nitride, etc.), metal materials (e.g., aluminum, copper, tungsten, titanium, tantalum, etc.), and metal semiconductor compounds (e.g., tungsten silicide, cobalt silicide, titanium silicide, etc.).

The devices included in the first semiconductor structure 100 and the devices included in the second semiconductor structure 200 may be connected through a corresponding conductive structure. For example, the capacitor group 101 and the voltage regulation circuit 250 may be connected through a conductive structure in the first semiconductor structure (such as a metal via, the metal layer 150, the first bonding structure 110, etc. in the first semiconductor structure 100) and a conductive structure in the second semiconductor structure (such as a metal via, a metal layer, the second bonding structure 210, etc. in the second semiconductor structure 200).

In the technical solution provided in the examples of the present disclosure, in one semiconductor structure of a memory 40 (which includes two bonded semiconductor structures), capacitors 102 are connected in parallel to form a capacitor group 101 in a charge pump, and a voltage regulation circuit 250 in the charge pump is provided in another semiconductor structure of the memory. Since the plurality of capacitors 102 in the capacitor group 101 are connected in parallel by connecting to the metal layer 150 in the semiconductor structure (e.g., first semiconductor structure), in the technical solution provided in the present disclosure, the number of capacitors 102 connected in parallel in the capacitor group 101 may be controlled by controlling the number of capacitors connected to the metal layer 150, thereby providing a flexible control on the total capacitance of the capacitor group 101 in the charge pump.

For example, the capacitor group 101 includes M capacitors, and since the M capacitors are in parallel, the total capacitance of the capacitor group is the sum of capacitances of the M capacitors. That is to say, the total capacitance of the capacitor group may be controlled by controlling the value of M, where M is an integer greater than 1.

In the following examples, a more detailed description will be provided to the specific connection methods between the plurality of capacitors 102 and the metal layer 150.

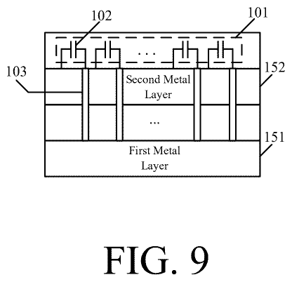

In some examples, referring to FIG. 9, the metal layer 150 includes a first metal layer 151 and a second metal layer 152.

In some examples, the first metal layer 151 and the second metal layer 152 are different metal layers in the first semiconductor structure 100.

The first ends of the plurality of capacitors 102 are each connected to the first metal layer 151, which is configured to connect the first ends of the plurality of capacitors with each other. The first metal layer 151 being configured to connect the first ends of the plurality of capacitors 102 with each other refers to a conductor structure in the first metal layer 151 (such as a metal routing in the first metal layer 151) connecting the first ends of the plurality of capacitors 102 with each other.

In some examples, referring to FIG. 9, for each capacitor 102 in the plurality of capacitors 102, the first end of the capacitor 102 is connected to an end of the first connection structure 103 corresponding to the capacitor, and another end of the first connection structure 103 corresponding to the capacitor 102 is connected to the first metal layer 151. Different capacitors of the plurality of capacitors 102 correspond to different first connection structures 103.

The first connection structure may be any conductive structure, such as a metal via.

In the above example, each capacitor 102 of the plurality of capacitors 102 is connected to the first metal layer 151 through a corresponding first connection structure 103. Therefore, in the memory 40, by controlling the number of first connection structures 103 configured for the capacitor group 101 (such as the number of metal vias), the total capacitance of the capacitor group 101 may be controlled flexibly.

The second ends of the plurality of capacitors 102 are each connected to the second metal layer 152, which is configured to connect the second ends of the plurality of capacitors with each other. The second metal layer 152 being configured to connect the second ends of the plurality of capacitors 102 with each other refers to a conductor structure in the second metal layer 152 (such as a metal routing in the second metal layer 152) connecting the second ends of the plurality of capacitors 102 with each other.

In some examples, for each capacitor 102 of the plurality of capacitors 102, the second end of the capacitor 102 is connected to an end of the second connection structure corresponding to the capacitor, and another end of the second connection structure corresponding to the capacitor 102 is connected to the second metal layer 152. Different capacitors of the plurality of capacitors 102 correspond to different second connection structures.

In some other examples, the second ends of the plurality of capacitors 102 are each directly connected to the second metal layer 152 without using the aforementioned second connection structure.

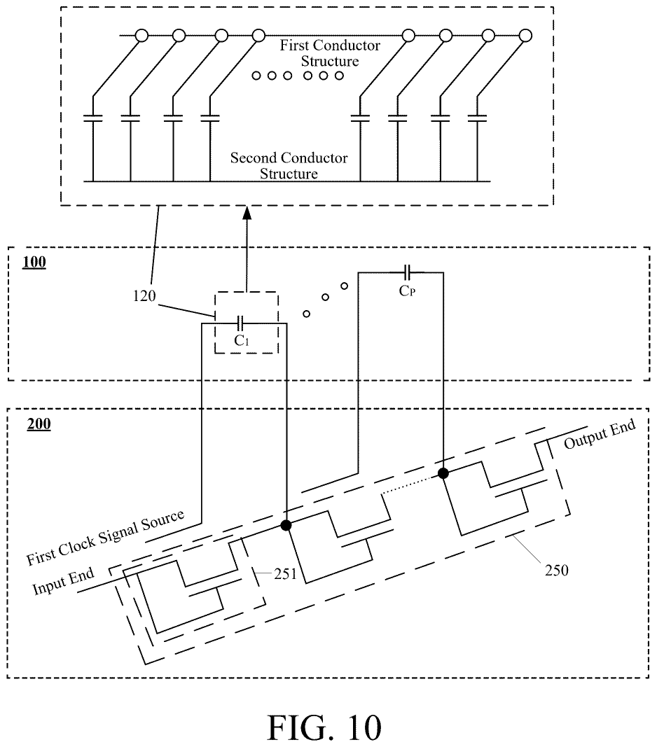

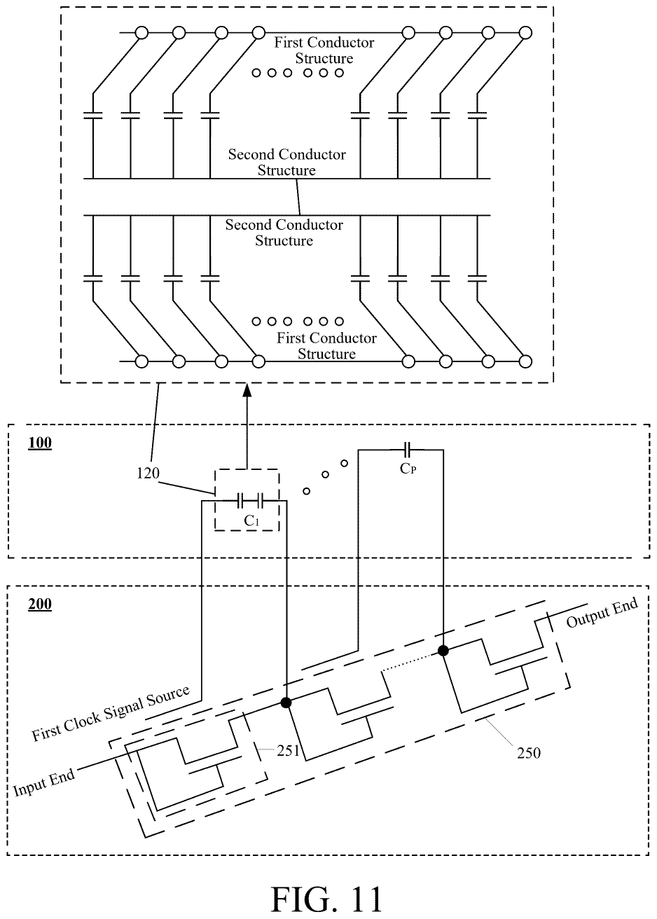

In some examples, referring to FIG. 10 or FIG. 11, the charge pump includes a first capacitor circuit 120, with N capacitor groups 101 in the first capacitor circuit 120. The first metal layer 151 includes N first conductor structures, and the second metal layer 152 includes N second conductor structures, where N is a positive integer.

The first conductor structure is a conductive structure in the first metal layer 151 (such as a metal routing in the first metal layer 151), and the second conductor structure is a conductive structure in the second metal layer 152 (such as a metal routing in the second metal layer 152).

In the i-th capacitor group 101 of N capacitor groups 101, the first ends of the plurality of capacitors 102 are each connected to the i-th first conductor structure of N first conductor structures, and the second ends of the plurality of capacitors 102 are connected to the i-th second conductor structure of N second conductor structures, where i is a positive integer less than or equal to N.

In some examples, an end of the first capacitor circuit 120 is connected to the voltage regulation circuit 250, and the second semiconductor structure 200 includes a first clock signal source connected to another end of the first capacitor circuit 120.

In some examples, referring to FIG. 10, in the case where N is equal to 1, e.g., the first capacitor circuit 120 includes one capacitor group 101, the first metal layer 151 includes one first conductor structure, and the second metal layer 152 includes one second conductor structure, the first conductor structure is connected to the voltage regulation circuit 250, and the second conductor structure is connected to the first clock signal source.

In some examples, in the case where N is greater than 1, N capacitor groups 101 may be connected in series by connecting different conductor structures in the same metal layer, which will be illustrated in the following examples.

In the case where N is an even number, the 1st first conductor structure of N first conductor structures is connected to the voltage regulation circuit 250, the j-th second conductor structure of N second conductor structures is connected to the (j+1)th second conductor structure of N second conductor structures, the k-th first conductor structure of N first conductor structures is connected to the (k+1)th first conductor structure of N first conductor structures, and the N-th first conductor structure of N first conductor structures is connected to the first clock signal source, where j is a positive odd number less than N, and k is a positive even number less than N.

For example, referring to FIG. 11, in the case where N is equal to 2, the 1st first conductor structure of two first conductor structures is connected to the voltage regulation circuit 250, the 1st second conductor structure of two second conductor structures is connected to the 2nd second conductor structure of the two second conductor structures, and the 2nd first conductor structure of the two first conductor structures is connected to the first clock signal source. As shown in FIG. 11, by connecting two second conductor structures (the 1st second conductor structure and the 2nd second conductor structure) in the second metal layer 152, two capacitor groups 101 are connected in series as the first capacitor circuit 120.

In the case where N is an odd number greater than 1, the 1st first conductor structure of N first conductor structures is connected to the voltage regulation circuit, the j-th second conductor structure of N second conductor structures is connected to the (j+1)th second conductor structure of N second conductor structures, the k-th first conductor structure of N first conductor structures is connected to the (k+1)th first conductor structure of N first conductor structures, and the N-th second conductor structure of N second conductor structures is connected to the first clock signal source.

For example, in the case where N is equal to 3, the 1st first conductor structure of three first conductor structures is connected to the voltage regulation circuit 250, the 1st second conductor structure of three second conductor structures is connected to the 2nd second conductor structure of the three second conductor structures, the 2nd first conductor structure of the three first conductor structures is connected to the 3rd first conductor structure of the three first conductor structures, and the 3rd second conductor structure of the three second conductor structures is connected to the first clock signal source. In this example, by connecting two second conductor structures (the 1st second conductor structure and the 2nd second conductor structure) in the second metal layer 152, and connecting two first conductor structures (the 2nd first conductor structure and the 3rd first conductor structure) in the first metal layer 151, three capacitor groups 101 are connected in series as the first capacitor circuit 120.

In some examples, in the case where N is greater than 1, at least two capacitor groups of N capacitor groups comprise different numbers of capacitors. For example, in the case where N is equal to 2, a first capacitor group includes 10 capacitors, and a second capacitor group may include 12 capacitors.

In the above example, the first capacitor circuit 120, which is connected to each of the voltage regulation circuit 250 and the first clock signal source, may be composed of a plurality of capacitor groups 101 in addition to being composed of a single capacitor group 101, and the plurality of capacitor groups 101 may include different numbers of capacitors. As can be seen, the configuration of the first capacitor circuit 120 is highly flexible.

In some examples, the first semiconductor structure 100 comprises a plurality of capacitor circuits in a charge pump, with an end of a capacitor circuit connected to the voltage regulation circuit 250. The capacitor circuit comprises at least one capacitor group, and in the case where the capacitor circuit includes a plurality of capacitor groups, the plurality of capacitor groups are sequentially connected in series.

The plurality of capacitor circuits mentioned above may include the first capacitor circuit 120 introduced in the above example. In a capacitor circuit, the implementation of a plurality of capacitor groups 101 sequentially connected in series may refer to the implementation of N capacitor groups 101 sequentially connected in series in the first capacitor circuit 120 in the above example (in the case where N is greater than 1), which will not be repeated here.

In some examples, another end of the capacitor circuit is connected to the clock signal source in the second semiconductor structure 200.

In some examples, referring to FIG. 10 or FIG. 11, the first semiconductor structure 100 includes P capacitor circuits (C₁~C_{P}) in the charge pump, and the voltage regulation circuit 250 includes P+1 voltage regulation sub-circuits 251 sequentially connected in series.

In some examples, the voltage regulation sub-circuit 251 is configured to control the charging and discharging process of the capacitor circuit, thereby achieving voltage regulation. The above voltage regulation sub-circuit 251 may include various devices such as a diode, a metal oxide semiconductor field-effect transistor, a complementary metal oxide semiconductor device, a charge transfer switch, a bipolar transistor, etc. The specific device types included in the voltage regulation sub-circuit 251 are not limited in the present disclosure.

The input end of the 1st voltage regulation sub-circuit of the P+1 voltage regulation sub-circuits 251 is connected to the input end of the charge pump, and the output end of the (P+1)th voltage regulation sub-circuit of the P+1 voltage regulation sub-circuits is connected to the output end of the charge pump.

An end of the r-th capacitor circuit of P capacitor circuits is connected to the output end of the r-th voltage regulation sub-circuit and the input end of the (r+1)th voltage regulation sub-circuit of P+1 voltage regulation sub-circuits, where r is a positive integer less than or equal to P.

For example, in the case where P=2, the input end of the 1st voltage regulation sub-circuit of three voltage regulation sub-circuits 251 is connected to the input end of the charge pump, and the output end of the 3rd voltage regulation sub-circuit is connected to the output end of the charge pump. An end of the 1st capacitor circuit of two capacitor circuits is connected to the output end of the 1st voltage regulation sub-circuit and the input end of the 2nd voltage regulation sub-circuit in the three voltage regulation sub-circuits 251. An end of the 2nd capacitor circuit in the two capacitor circuits is connected to the output end of the 2nd voltage regulation sub-circuit and the input end of the 3rd voltage regulation sub-circuit in the three voltage regulation sub-circuits 251.

In some examples, at least two capacitor circuits in the plurality of capacitor circuits include different numbers of capacitor groups.

For example, referring to FIG. 11, in the plurality of capacitor circuits, capacitor circuit C₁ includes two capacitor groups 101, while capacitor circuit C_{P} only includes one capacitor group 101.

In some examples, the number of capacitors included in the first capacitor group is different from the number of capacitors included in the second capacitor group, wherein the first capacitor group and the second capacitor group are capacitor groups in different capacitor circuits of a plurality of capacitor circuits.

For example, referring to FIG. 10, in a plurality of capacitor circuits, the capacitor group 101 in capacitor circuit C₁ may include 10 capacitors, while the capacitor group 101 in capacitor circuit C_{P} may include 10 capacitors, or may include less than or more than 10 capacitors.

In the above examples, different capacitor circuits may include different numbers of capacitor groups, and capacitor groups in different capacitor circuits may also include different numbers of capacitors. That is to say, based on the charge pump architecture provided in the present disclosure, the structure of capacitor circuits at various locations in the charge pump may be flexibly configured according to actual requirement. Therefore, the charge storage capacity of capacitor circuits at various locations may be flexibly configured according to actual requirement.

In some examples, the first semiconductor structure 100 and the second semiconductor structure 200 are stacked along a first direction, and a plurality of capacitor circuits and the voltage regulation circuit 250 at least partially overlap in a view perpendicular to the first direction.

In some examples, the first semiconductor structure 100 further includes a memory cell array 41, which comprises a plurality of memory cells 401. The memory cell 401 includes a capacitor structure 403 and a transistor 402 that are connected together.

In some examples, the capacitor structure 403 in the memory cell 401 has the same structure as the capacitor 102 in the capacitor group 101.

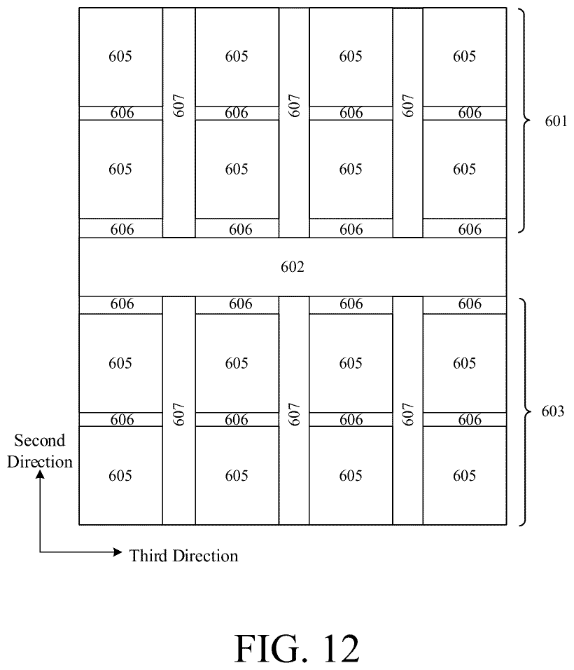

Referring to FIG. 12, FIG. 12 shows a schematic diagram of arrangement of regions of a memory provided in one example of the present disclosure.

In some examples, as shown in FIG. 12, the memory 40 includes a first memory region 601, a first peripheral region 602, and a second memory region 603 arranged along a second direction. The first peripheral region 602 is located between the first memory region 601 and the second memory region 603. The memory cell array 41 is located in the first memory region 601 and in the second memory region 603. The second direction is perpendicular to the first direction. Furthermore, any two directions of the first direction, the second direction, and a third direction in the following examples are perpendicular to each other.

In some examples, the first memory region 601 and the second memory region 603 include a first circuit region 605, a second circuit region 606, and a third circuit region 607. A plurality of first circuit regions 605 are arranged in an array along the second and third directions, with each memory bank corresponding to one first circuit region 605 (e.g., one memory bank is provided in each first circuit region 605). For example, as shown in FIG. 12, the memory 40 includes 16 first circuit regions 605, and the memory cell array 401 includes 16 memory banks Bank0-Bank15, each of which corresponds to one first circuit region 605. It should be noted that the number of first circuit regions 605 in the accompanying figures is only an example and is not intended to limit the number of first circuit regions 605 in the examples of the present disclosure.

As shown in FIG. 12, the second circuit region 606 is adjacent to the first circuit region 605 along the second direction, and the third circuit region 607 is located between adjacent first circuit regions 605 along the third direction. In the first circuit region 605, a control circuit of each memory block of the corresponding memory bank may also be provided, such as a Sensing Amplifier (SA) circuit, a Word Line Driver (WLD) circuit, etc. A column control circuit of the corresponding memory bank, such as a column decoding circuit, may be provided in the second circuit region 606. A row control circuit of the corresponding memory bank, such as a row decoding circuit, may be provided in the third circuit region 607. The first peripheral region 602 may include a portion of the first semiconductor structure 100 as well as a portion of the second semiconductor structure 200. For example, the plurality of capacitor circuits and the voltage regulation circuit 250 of the charge pump circuit may be provided in the first peripheral region 602. As an example, the view perpendicular to the first direction mentioned above may be understood as a view parallel to the second and third directions shown in FIG. 12. That is, the plurality of capacitor circuits and the voltage regulation circuit 250 are all included in the first peripheral region 602 in a view perpendicular to the first direction, and at least partially overlap.

In addition to the aforementioned capacitor circuits and the voltage regulation circuit 250, control circuits corresponding to all memory banks may also be provided in the first peripheral region 602, such as command buffers, command decoders, address buffers, data input/output buffers, mode registers, etc.

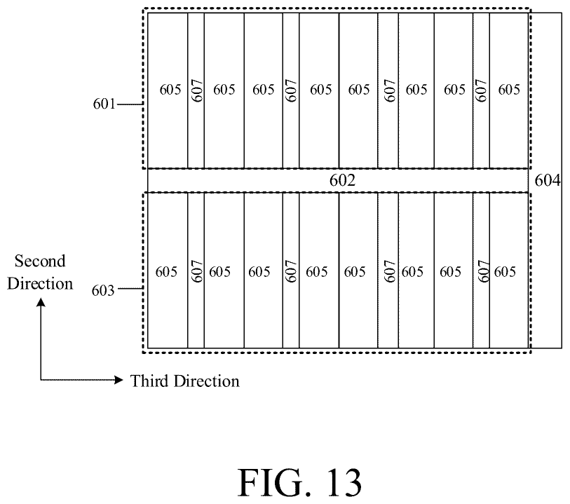

Referring to FIG. 13, FIG. 13 shows a schematic diagram of arrangement of regions of a memory provided in another example of the present disclosure.

As shown in FIG. 13, the memory 40 further includes a second peripheral region 604, in addition to the first memory region 601, the first peripheral region 602, and the second memory region 603 arranged along the second direction. The first memory region 601, the first peripheral region 602, and the second memory region 603 are located on the same side of two opposite sides of the second peripheral region 604 along the third direction.

The second peripheral region 604 may include a portion of the first semiconductor structure 100 as well as a portion of the second semiconductor structure 200. For example, the plurality of capacitor circuits mentioned above and the voltage regulation circuit 250 of the charge pump circuit may be provided in the first peripheral region 604. As an example, the view perpendicular to the first direction mentioned above may be understood as a view parallel to the second and third directions shown in FIG. 13. That is, the plurality of capacitor circuits and the voltage regulation circuit 250 are all included in the second peripheral region 604 in a view perpendicular to the first direction, and at least partially overlap.

In the above examples, the plurality of capacitor circuits and the voltage regulation circuit 250 at least partially overlap in a view perpendicular to the first direction, fully utilizing the stack structure of memory 40 and helping to reduce memory area. In addition, arranging the plurality of capacitor circuits and the voltage regulation circuit 250 in the same region also helps to save metal routing connecting them.

In some examples, the first semiconductor structure 100 further includes a memory cell array 41, and the memory cell array 41 and a plurality of capacitor circuits do not overlap in a view perpendicular to the first direction.

For example, referring to FIG. 12, the above view perpendicular to the first direction may be understood as a view parallel to the second and third directions shown in FIG. 12. The memory cell array 41 is included in the first memory region 601 and the second memory region 603, while the plurality of capacitor circuits are included in the first peripheral region 602. As can be seen, the memory cell array 41 and the plurality of capacitor circuits do not overlap in a view perpendicular to the first direction.

For example, referring to FIG. 13, the above view perpendicular to the first direction may be understood as a view parallel to the second and third directions shown in FIG. 13. The memory cell array 41 is included in the first memory region 601 and the second memory region 603, while the plurality of capacitor circuits are included in the second peripheral region 604. As can be seen, the memory cell array 41 and the plurality of capacitor circuits do not overlap in a view perpendicular to the first direction.

As shown above, the technical solutions provided in the examples of the present disclosure support a flexible configuration for the charge storage capacity of different portions of the charge pump, so that the efficiency and current carrying capacity of the charge pump are more balanced, so as to meet the design requirements of the charge pump in various scenarios.

For example, Table 1 shows the differences in relevant parameters for three different charge pumps with the same input signal and expected output high voltage signal.

TABLE 1

| | Charge pump1 | Charge pump2 | Charge pump3 |
|---|---|---|---|
| Output current | 15 mA (milliamperes) | 20 mA | 25 mA |
| Efficiency | 40% | 41% | 42% |
| Ripple | 10 mV (millivolts) | 20 mV | 40 mV |

The above three charge pumps all include the capacitor groups 101 provided in the examples of the present disclosure, but have different specific configurations, e.g., capacitor groups 101 comprise different numbers of capacitors 102. As can be seen, changes in the configuration of the charge pump will cause variations in performance parameters of the charge pump such as output current, efficiency, ripple, etc. Therefore, the technical solution provided in the examples of the present disclosure is beneficial for those skilled in the art to configure the charge pump according to actual requirement.

In some examples, a memory system is further provided, which may comprise a controller and a memory provided in any one of the examples of the present disclosure. The controller is coupled to the memory to control the memory to store data.

In some examples, an electronic device is further provided, which comprises a host and a memory system coupled to the host. The memory system comprises a controller and a memory provided in any one of the examples of the present disclosure, and the controller is coupled to the memory to control the memory to store data.

A more detailed illustration of the memory system and the electronic device here may refer to the description of the memory system and the electronic device in the above examples, which will not be repeated here.

It should be understood that the term “multiple” mentioned herein refers to two or more. The term “and/or” describes the association relationship between related objects, indicating that there may be three types of relationships. For example, A and/or B may represent: A alone, A and B, and B alone. The symbol “/” generally indicates that the associated object before and after has an “or” relationship. In addition, the numbering of steps described herein only illustrates one possible order of execution between the steps. In some other examples, the above steps may not be executed in the order of the numbering, e.g., two steps with different numbers may be executed simultaneously, or two steps with different numbers may be executed in an order opposite to that shown in the figures, which is not limited by the examples of the present disclosure.

Examples of the present disclosure provide a memory, a memory system and an electronic device. The technical solution provided by the examples of the present disclosure is as follows:

According to one aspect of examples of the present disclosure, a memory is provided. The memory comprises a first semiconductor structure and a second semiconductor structure that are bonded to each other.

The first semiconductor structure comprises a metal layer and a capacitor group in a charge pump, and the capacitor group comprises a plurality of capacitors.

The plurality of capacitors are connected to the metal layer, and the metal layer is configured to connect the plurality of capacitors in parallel.

The second semiconductor structure comprises a voltage regulation circuit in the charge pump.

According to one aspect of examples of the present disclosure, a memory system is provided. The memory system comprises a controller and a memory described above. The controller is coupled to the memory to control the memory to store data.

According to one aspect of examples of the present disclosure, an electronic device is provided. The electronic device comprises a host and a memory system coupled to the host. The memory system comprises a controller and a memory described above. The controller is coupled to the memory to control the memory to store data.

The technical solution provided by the examples of the present disclosure at least has the following advantageous effects:

In one semiconductor structure of a memory comprising two bonded semiconductor structures, capacitors are connected in parallel to form a capacitor group in a charge pump, and a voltage regulation circuit in the charge pump is provided in another semiconductor structure of the memory. Since a plurality of capacitors in the capacitor group are connected in parallel by being connected to a metal layer in the semiconductor structure (the first semiconductor structure), the technical solution provided by the present disclosure may control the number of capacitors connected in parallel in the capacitor group by controlling the number of capacitors connected to the metal layer, thereby providing a flexible control on the total capacitance of the capacitor group in the charge pump.

The above are only some examples of the present disclosure and are not intended to limit the present disclosure. Any modifications, equivalent substitutions, adaptations, etc. made within the spirit and principles of the present disclosure shall be encompassed within the protection scope of the present disclosure.

What is claimed is:

1. A memory comprising:
a first semiconductor structure comprising a metal layer and a capacitor group in a charge pump, the capacitor group comprises a plurality of capacitors, the plurality of capacitors are connected to the metal layer, and the metal layer is configured to connect the plurality of capacitors in parallel; and
a second semiconductor structure bonded to the first semiconductor structure, the second semiconductor structure comprises a voltage regulation circuit in the charge pump.

2. The memory of claim 1, wherein:
the metal layer comprises a first metal layer and a second metal layer;
first ends of the plurality of capacitors are connected to the first metal layer;
the first metal layer is configured to connect the first ends of the plurality of capacitors with each other;
second ends of the plurality of capacitors are connected to the second metal layer; and
the second metal layer is configured to connect the second ends of the plurality of capacitors with each other.

3. The memory of claim 2, wherein:
for each capacitor of the plurality of capacitors:
a first end of the capacitor is connected to an end of a first connection structure corresponding to the capacitor; and
another end of the first connection structure corresponding to the capacitor is connected to the first metal layer; and
different capacitors of the plurality of capacitors correspond to different first connection structures.

4. The memory of claim 2, wherein:
the charge pump comprises a first capacitor circuit;
the first capacitor circuit comprises N capacitor groups;
the first metal layer comprises N first conductor structures;
the second metal layer comprises N second conductor structures, wherein N is a positive integer; and
in an i-th capacitor group of the N capacitor groups, the first ends of the plurality of capacitors are each connected to an i-th first conductor structure of the N first conductor structures, and the second ends of the plurality of capacitors are each connected to an i-th second conductor structure of the N second conductor structures, wherein i is a positive integer less than or equal to N.

5. The memory of claim 4, wherein:
an end of the first capacitor circuit is connected to the voltage regulation circuit;
the second semiconductor structure comprises a first clock signal source connected to another end of the first capacitor circuit; and
when N is equal to 1, the i-th first conductor structure is connected to the voltage regulation circuit, and the i-th second conductor structure is connected to the first clock signal source.

6. The memory of claim 4, wherein:
an end of the first capacitor circuit is connected to the voltage regulation circuit;
the second semiconductor structure comprises a first clock signal source connected to another end of the first capacitor circuit;
when N is an even number, a 1st first conductor structure of the N first conductor structures is connected to the voltage regulation circuit, a j-th second conductor structure of the N second conductor structures is connected to a (j+1)th second conductor structure of the N second conductor structures, a k-th first conductor structure of the N first conductor structures is connected to a (k+1)th first conductor structure of the N first conductor structures, and an N-th first conductor structure of the N first conductor structures is connected to the first clock signal source;
when N is an odd number greater than 1, the 1st first conductor structure of the N first conductor structures is connected to the voltage regulation circuit, the j-th second conductor structure of the N second conductor structures is connected to a (j+1)th second conductor structure of the N second conductor structures, the k-th first conductor structure of the N first conductor structures is connected to a (k+1)th first conductor structure of the N first conductor structures, and an N-th second conductor structure of the N second conductor structures is connected to the first clock signal source;
j is a positive odd number less than N; and
k is a positive even number less than N.

7. The memory of claim 4, wherein, when N is greater than 1, at least two of the N capacitor groups comprise different numbers of capacitors.

8. The memory of claim 1, wherein:
the first semiconductor structure comprises a plurality of capacitor circuits in the charge pump;
an end of the capacitor circuit is connected to the voltage regulation circuit;
the capacitor circuit comprises the capacitor group; and
when the capacitor circuit comprises a plurality of capacitor groups, the plurality of capacitor groups are sequentially connected in series.

9. The memory of claim 8, wherein:
the first semiconductor structure comprises P capacitor circuits in the charge pump;
the voltage regulation circuit comprises P+1 voltage regulation sub-circuits;
the P+1 voltage regulation sub-circuits are sequentially connected in series;
P is an integer greater than 1;
an input end of a 1st voltage regulation sub-circuit of the P+1 voltage regulation sub-circuits is connected to an input end of the charge pump;
an output end of a (P+1)th voltage regulation sub-circuit of the P+1 voltage regulation sub-circuits is connected to an output end of the charge pump;
an end of a r-th capacitor circuit of the P capacitor circuits is connected to an output end of a r-th voltage regulation sub-circuit and an input end of a (r+1)th voltage regulation sub-circuit of the P+1 voltage regulation sub-circuits; and
r is a positive integer less than or equal to P.

10. The memory of claim 8, wherein at least two of the plurality of capacitor circuits comprise different numbers of capacitor groups.

11. The memory of claim 8, wherein:
a number of capacitors in a first capacitor group is different from a number of capacitors in a second capacitor group; and
the first capacitor group and the second capacitor group are in different capacitor circuits of the plurality of capacitor circuits.

12. The memory of claim 8, wherein the first semiconductor structure and the second semiconductor structure are stacked along a first direction, and the plurality of capacitor circuits and the voltage regulation circuit at least partially overlap in a view perpendicular to the first direction.

13. The memory of claim 12, wherein the first semiconductor structure further comprises a memory cell array, and the memory cell array and the plurality of capacitor circuits do not overlap in the view perpendicular to the first direction.

14. The memory of claim 13, wherein:
the memory cell array comprises a plurality of memory cells;
each of the memory cells comprising a capacitor structure and a transistor; and
the capacitor structure is connected to the transistor.

15. A memory system, comprising:
a memory comprising:
a first semiconductor structure and a second semiconductor structure that are bonded to each other, wherein:
the first semiconductor structure comprises a metal layer and a capacitor group in a charge pump;
the capacitor group comprises a plurality of capacitors;
the plurality of capacitors are connected to the metal layer;
the metal layer is configured to connect the plurality of capacitors in parallel; and
the second semiconductor structure comprises a voltage regulation circuit in the charge pump; and
a controller coupled to the memory to control the memory to store data.

16. The memory system of claim 15, wherein:
the metal layer comprises a first metal layer and a second metal layer;
first ends of the plurality of capacitors are connected to the first metal layer;
the first metal layer is configured to connect the first ends of the plurality of capacitors with each other;
second ends of the plurality of capacitors are connected to the second metal layer; and
the second metal layer is configured to connect the second ends of the plurality of capacitors with each other.

17. The memory system of claim 16, wherein:
for each capacitor of the plurality of capacitors:
a first end of the capacitor is connected to an end of a first connection structure corresponding to the capacitor; and
another end of the first connection structure corresponding to the capacitor is connected to the first metal layer; and
different capacitors of the plurality of capacitors correspond to different first connection structures.

18. The memory system of claim 16, wherein:
the charge pump comprises a first capacitor circuit;
the first capacitor circuit comprises N capacitor groups;
the first metal layer comprises N first conductor structures;
the second metal layer comprises N second conductor structures, wherein N is a positive integer; and
in an i-th capacitor group of the N capacitor groups, the first ends of the plurality of capacitors are each connected to an i-th first conductor structure of the N first conductor structures, and the second ends of the plurality of capacitors are each connected to an i-th second conductor structure of the N second conductor structures, wherein i is a positive integer less than or equal to N.

19. The memory system of claim 18, wherein:
an end of the first capacitor circuit is connected to the voltage regulation circuit;
the second semiconductor structure comprises a first clock signal source connected to another end of the first capacitor circuit; and
when N is equal to 1, the i-th first conductor structure is connected to the voltage regulation circuit, and the i-th second conductor structure is connected to the first clock signal source.

20. An electronic device comprising:
a host; and
a memory system coupled to the host and comprising:
a memory comprising:
a first semiconductor structure and a second semiconductor structure that are bonded to each other, wherein:
the first semiconductor structure comprises a metal layer and a capacitor group in a charge pump;
the capacitor group comprises a plurality of capacitors;
the plurality of capacitors are connected to the metal layer;
the metal layer is configured to connect the plurality of capacitors in parallel; and
the second semiconductor structure comprises a voltage regulation circuit in the charge pump; and
a controller coupled to the memory to control the memory to store data.
